(19) United States
(12) Patent Application Publication
(10) Pub. No.: US 2008/0171221 A1
(43) Pub. Date: Jul. 17, 2008

(54) Thermal Barrier Coating

(75) Inventors: Luah K. Hai, Singapore (SG); Garimella B. Rao, Singapore (SG)

Correspondence Address: BACHMAN & LAPOINTE, P.C. (P&W), 900 CHAPEL STREET, SUITE 1201, NEW HAVEN, CT, 06510-2802, US

(73) Assignees: UNITED TECHNOLOGIES CORPORATION, Hartford, CT (US); Turbine Overhaul Services Private Limited, Singapore (SG)

(21) Appl. No.: 11/925,062

(22) Filed: Oct. 26, 2007

Related U.S. Application Data
(63) Continuation of application No. 11/184,265, filed on Jul. 18, 2005, now abandoned.

(30) Foreign Application Priority Data
May 27, 2005 (SG) 200503371-7

(51) Int. Cl. B32B 15/04; B05D 1/36; C23C 8/00; C23C 16/00

(52) U.S. Cl. 428/621; 427/404; 427/585; 427/250

(57) ABSTRACT

A coated article includes a substrate and a thermal barrier layer. An aluminide layer is between the substrate and the thermal barrier layer. A PtAl₂ layer is between the aluminide layer and the thermal barrier layer.

### CROSS-REFERENCE TO RELATED APPLICATION

This is a continuation of Ser. No. 11/184,265, filed Jul. 18, 2005, and entitled THERMAL BARRIER COATING, the disclosure of which is incorporated by reference herein in its entirety as if set forth at length.

### BACKGROUND OF THE INVENTION

This invention relates to thermal barrier coatings, and more particularly to bond coats for thermal barrier coatings on turbine components.

Gas turbine engine components (e.g., blades, vanes, seals, combustor panels, and the like) are commonly formed of nickel- or cobalt based superalloys. Desired operating temperatures often exceed that possible for the alloys alone. Thermal barrier coatings (TBCs) are in common use on such components to permit use at elevated temperatures. Various coating compositions (e.g., ceramics) and various coating methods (e.g., electron beam physical vapor deposition (EB-PVD) and plasma spray deposition) are known.

An exemplary modern coating system is applied to the superalloy substrate by an EB-PVD technique. An exemplary coating system includes a metallic bondcoat layer (e.g., an overlay of NiCoCrAlY alloy or diffusion aluminide) atop the substrate. A thermally insulating ceramic topcoat layer (e.g., zirconia stabilized with yttria (YSZ)) is deposited atop the bondcoat. During this deposition, a thermally grown oxide layer (TGO) (e.g., alumina) may form on the bondcoat and intervenes between the remaining underlying portion of the bondcoat and the topcoat.

In one exemplary coating system and associated process, a nickel-based superalloy substrate is initially plated with platinum. A heating step produces diffusion between the substrate and plating. After this platinum diffusion, a coating of aluminum is applied. During the aluminum application diffusion may form a platinum-containing aluminide. After this coating, a further heating step causes further diffusion resulting in greater uniformity by diffusing in excess surface aluminum and diffusing out nickel from the substrate. Thereafter, the YSZ coating is deposited by EB-PVD.

### SUMMARY OF THE INVENTION

One aspect of the invention involves a coated article including a substrate and a thermal barrier layer. An aluminide layer is between the substrate and the thermal barrier layer. A PtAl₂ layer is between the aluminide layer and the thermal barrier layer.

A method comprises applying an aluminum-containing first layer to a substrate, applying a platinum-containing second layer atop the first layer, causing diffusion of aluminum from the first layer into the second layer so as to produce a PtAl₂ alloy, and applying a thermal barrier layer atop the PtAl₂ alloy.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 is a basic flowchart of a process for forming a coated article.

FIG. 2 is a sectional photomicrograph of a coated article.

FIG. 3 is a flowchart of an alternative process for forming a coated article.

Like reference numbers and designations in the various drawings indicate like elements.

### DETAILED DESCRIPTION

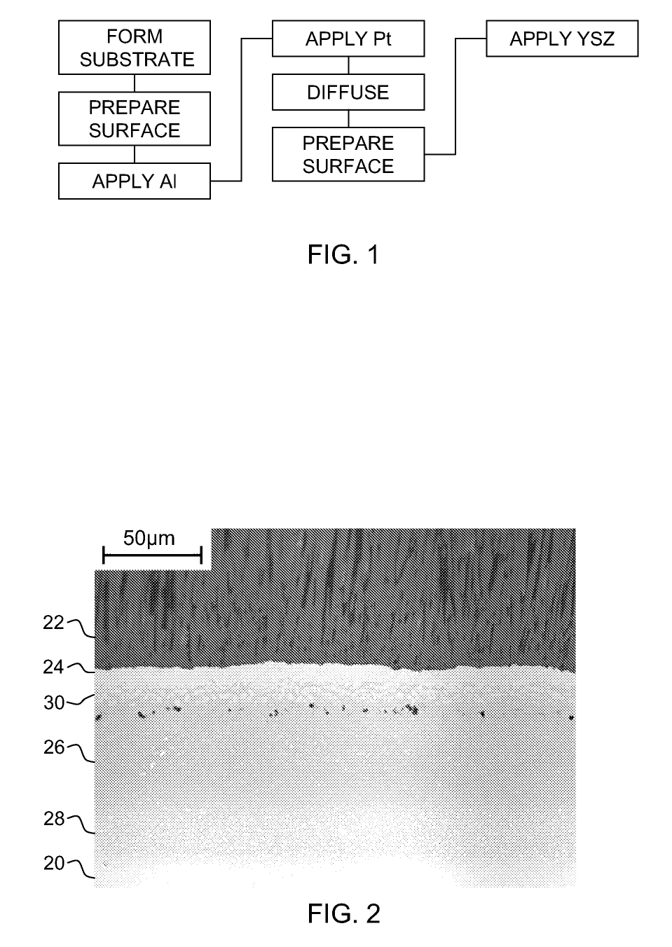

FIG. 1 shows an exemplary process for forming a coated article. The exemplary process includes forming a substrate to be coated. Exemplary substrates are gas turbine engine components formed of nickel- or cobalt-based superalloys. One component of particular interest is a turbine section blade. The substrate may be formed by one or more steps (e.g., casting and machining). Alternatively, in a re-coating situation the substrate may have previously been formed and may be subject to removal of an existing coating and optional patching, crack filling, and the like.

The surface of the substrate to be coated may be prepared by chemical and/or mechanical means (e.g., cosmetic blasting as is known in the art). Thereafter, an aluminum-containing material is applied directly to the substrate surface. The application of the aluminum-containing material will serve to at least initially form an aluminide. Many application techniques are used in the art and are possible. An exemplary technique involves a conventional gas phase coating. Such a process involves placing the substrate in proximity to a coating media source generating coating vapors. This may be distinguished from chemical vapor deposition (CVD) techniques wherein the source is more remote. In CVD coating, the substrate is kept in a container which is separate from the coating media container(s). The CVD coating material vapors are delivered via separate carrier gas. In gas phase coating the substrate and the coating media are in the same container and the substrate does not touch the coating media ( from which the coating vapors are generated).

An exemplary source material comprises aluminum chrome with ammonium fluoride, ammonium chloride, or aluminum flouride as an activator. Exemplary aluminum chrome is a granular alloy of aluminum and chromium in a eutectic 55:45 weight percent ratio. Upon heating of the aluminum chrome and activator (e.g., in a pan under controlled atmosphere conditions such as an inert gas (e.g., argon)), the activator causes release of an aluminum vapor which condenses on the substrate. An exemplary deposition duration is less than eight hours (e.g., five to seven hours). During this deposition, diffusion from the substrate (e.g., especially of nickel) converts the applied aluminum-containing material into nickel aluminide. This aluminide will tend to have an NiAl/NiAl₂ composition further including other of the substrate alloying elements as alloying elements in the aluminide and/or as precipitates in the aluminide.

After the application of the aluminum-containing material and initial aluminide formation, a platinum-containing material is applied. The exemplary application involves electroplating of pure platinum. This application leaves a layer of the platinum-containing material atop the aluminide.

A diffusion step then produces diffusion of aluminum into the platinum layer and of platinum into the aluminide. An exemplary diffusion is caused by heating. Exemplary heating is to a temperature of at least 1850° F. (more preferably at least 1950° F.) for a time of at least five minutes (e.g., to about 1925° F. for about ten minutes in vacuum (e.g., 0.1 militorr or less) then 1975° F. for about four hours in argon).

After any additional surface preparation (e.g., polishing) the YSZ coating may be applied. An exemplary YSZ application is by EB-PVD.

FIG. 2 shows details of the coated article. The substrate has a largely undisturbed base portion 20 at the bottom of the figure. The YSZ layer 22 is at the top. The YSZ layer 22 is immediately atop a platinum-aluminum layer 24 produced by the diffusion of aluminum into the platinum plating. In an exemplary implementation, the layer 24 is a continuous PtAl₂ phase. The platinum-containing aluminide layer 26 is below the PtAl₂ layer 24. A transition region 30 between the layers 24 and 26 is not extremely abrupt and is characterized by moderately large inclusions of one layer's material within the other. However, the PtAl₂ is still seen as distinct from the aluminide layer 26 and the YSZ thermal barrier layer 22. The transition region 30 is located outboard of the original boundary between the aluminide and the platinum plating. This boundary is evidenced by the dark spots which may be coincident with the original surface of the substrate. Similarly, a diffusion region 28 may be between the undisturbed substrate base portion 20 and the aluminide 26.

An exemplary thickness of the YSZ layer 22 is at least 40 μm (e.g., 50-100 μm). An exemplary thickness of the PtAl₂ layer 24 is 5-20 μm. An exemplary thickness of the aluminide layer 26 is 25-100 μm.

Plating after the aluminum deposition may have one or more of several advantages. The plating may tend to provide a smooth surface by filling roughness imperfections in the aluminide. Exemplary roughness is 20-40 RA after diffusion. The smoothness promotes topcoat adhesion and associated spall resistance.

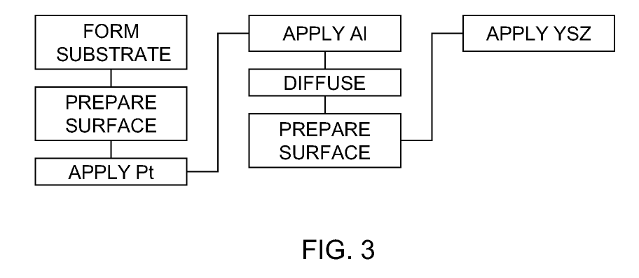

FIG. 3 shows an alternative process wherein the order of platinum and aluminum application is reversed. As distinguished from one prior art system wherein platinum is applied directly to a substrate, the platinum layer deposited in FIG. 3 is relatively thick (e.g., 5-8 μm). Also, there is substantially no separate diffusion step between the platinum application and the aluminum application. The subsequent diffusion heating (e.g., to at least 1850° F. (more preferably 1950° F.) for at least five minutes) serves to interdiffuse the platinum into the aluminum (forming the surface layer 24 as well as providing the platinum for the aluminide layer. An exemplary heating is to 1975° F. for about four hours in argon. The diffusion also passes substrate components (e.g., the nickel) into the aluminum to form the aluminide layer.

One or more embodiments of the present invention have been described. Nevertheless, it will be understood that various modifications may be made without departing from the spirit and scope of the invention. For example, the principles may be applied as modifications of various existing or yet-developed coating systems and techniques and equipment. Details of any such baseline coating or technique or equipment may influence details of any particular implementation. Accordingly, other embodiments are within the scope of the following claims.

What is claimed is:

1. An article comprising:
a substrate;
a thermal barrier first layer;
a second layer comprising aluminide between the substrate and the thermal barrier layer; and
a third layer comprising PtAl₂ between and distinct from the aluminide layer and the thermal barrier layer.

2. The article of claim 1 wherein:
the substrate consists essentially of a nickel-based superalloy.

3. The article of claim 1 wherein:
the first layer consists essentially of yttria-stabilized zirconia.

4. The article of claim 3 wherein:
the substrate consists essentially of a nickel-based superalloy.

5. The article of claim 1 wherein:
the second layer consists essentially of a platinum aluminide.

6. The article of claim 1 wherein:
the third layer has a thickness of 5-20 μm.

7. The article of claim 6 wherein:
the second layer has a thickness of 25-100 μm.

8. The article of claim 1 wherein:
the second layer has a thickness of 25-100 μm.

9. The article of claim 1 wherein the article consists essentially of:
the substrate;
the first layer;
the second layer;
the third layer; and
optionally transition regions.

10. The article of claim 9 wherein:
the second layer consists essentially of a platinum aluminide.

11. The article of claim 9 wherein:
the third layer has a thickness of 5-20 μm.

12. The article of claim 11 wherein:
the second layer has a thickness of 25-100 μm.

13. The article of claim 9 wherein:
the second layer has a thickness of 25-100 μm.

14. An article comprising:
a nickel-based superalloy substrate;
a YSZ first layer;
a nickel aluminide second layer between the substrate and the first layer; and
a PtAl₂ third layer between the second layer and the first layer.

15. The article of claim 14 wherein the article consists essentially of the substrate, first layer, second layer, and third layer, optionally including transition regions.

16. The article of claim 15 wherein:
the second layer has a thickness of 25-100 μm.

17. The article of claim 16 wherein:
the third layer has a thickness of 5-20 μm.

18. The article of claim 15 wherein:
the third layer has a thickness of 5-20 μm.

19. The article of claim 14 wherein:
the second layer has a thickness of 25-100 μm; and
the third layer has a thickness of 5-20 μm.

20. The article of claim 1 wherein the third layer is a continuous PtAl₂ phase.

21. The article of claim 20 wherein the continuous PtAl₂ phase has a thickness of 5-20 μm.

22. The article of claim 1 wherein the third layer comprises a majority, by weight, PtAl₂.

23. A method comprising:
applying an aluminum-containing first layer to a substrate;
applying a platinum-containing second layer atop the first layer;
causing diffusion of aluminum from the first layer into the second layer so as to produce a PtAl₂ alloy; and
applying a thermal barrier layer atop the PtAl₂ alloy.

24. The method of claim 23 wherein the applying the thermal barrier layer comprises electron beam physical vapor deposition of yttria-stabilized zirconia.

25. The method of claim 23 wherein:
the applying the first layer consists essentially of gas phase coating of aluminum chrome with an activator.

26. The method of claim 23 wherein:
the causing diffusion comprises heating to a temperature of at least 1850° F.

27. The method of claim 23 wherein:
the causing diffusion comprises heating to a temperature of at least 1900° F.

28. The method of claim 23 wherein:
the diffusion is at least as great as a diffusion caused by heating to a temperature of 1850° F. for a time of at least five minutes.

29. The method of claim 23 wherein:
the diffusion is at least as great as a diffusion caused by heating to a temperature of 1925° F. for a time of at least five minutes.

30. The method of claim 23 wherein:
the diffusion is at least as great as a diffusion caused by heating to a temperature of 1950° F. for a time of at least five minutes.

31. The method of claim 23 further comprising:
forming the substrate of a nickel-based superalloy.

32. The method of claim 23 further comprising:
preparing the substrate by surface blasting.

33. A method for coating a substrate comprising:
a step for applying an aluminum-containing first material;
a step for applying a platinum-containing second material different from the first material;
a step for forming a PtAl₂ layer from platinum of the second material and aluminum of the first material; and
a step for applying a thermal barrier layer.

34. The method of claim 33 wherein:
the step for forming a thermal barrier layer is performed after the step for forming the PtAl₂ layer.
